(19) United States
(12) Patent Application Publication
(10) Pub. No.: US 2011/0203082 A1
(43) Pub. Date: Aug. 25, 2011

(54) Press apparatus and method for manufacturing semiconductor device

(75) Inventor: Tohru Kumamoto, Kumamoto (JP)

(73) Assignee: Renesas Electronics Corporation, Kawasaki-shi (JP)

(21) Appl. No.: 12/929,806

(22) Filed: Feb. 16, 2011

(30) Foreign Application Priority Data
Feb. 25, 2010 (JP) 2010-040817

(51) Int. Cl. H01L 21/02; B30B 15/34

(52) U.S. Cl. 29/25.01; 100/102

(57) ABSTRACT

A press apparatus includes a bolster, a lower die holder that is mounted on the bolster to which a lower die (for example, die plate and die) is to be provided, a guide post that is vertically provided in the lower die holder, a guide bush that slides along the guide post, an upper die holder that is fixed to the guide bush to which an upper die (for example, punch plate and punch) is to be provided, and a heat transfer accelerating portion that contacts the guide post and the bolster and accelerates the transfer of heat from the guide post to the bolster.

This application is based on Japanese patent application No. 2010-040817, the content of which is incorporated hereinto by reference.

### BACKGROUND

1. Technical Field

The present invention relates to a press apparatus and a method for manufacturing a semiconductor device.

2. Related Art

A press apparatus including an upper die and a lower die is used to process (for example, bend or cut) a processing object such as a lead of a semiconductor device. The press apparatus includes a sliding portion formed by a guide post that is vertically provided and a guide bush that slides along the guide post in the vertical direction in order to relatively move the upper die and the lower die.

The press apparatus is disclosed in, for example, Japanese Laid-Open Patent Publication No. 07-245366. The press apparatus disclosed in Japanese Laid-Open Patent Publication No. 07-245366 includes a bending punch serving as an upper die, a bending die serving as a lower die, a Peltier element that is provided such that the heat absorption side thereof comes into contact with the rear surfaces of the bending punch and the bending die, and a heat sink that is provided on the heat dissipation side of the Peltier element. Japanese Laid-Open Patent Publication No. 07-245366 discloses a technique capable of suppressing the overheating of the bending punch and the bending die using the above-mentioned structure.

In order to process a processing object, such as a lead of a semiconductor device, with high accuracy, it is necessary to accurately position the upper die and the lower die and stably maintain the state. In order to accurately position the upper die and the lower die, it is necessary to set the clearance (allowance) between the guide post and the guide bush of the sliding portion to a very small value. In addition, it is necessary to increase a pressing speed in order to improve productivity and it is necessary to repeatedly perform a pressing process for a long time in order for mass production. In this case, the sliding portion of the press apparatus is overheated and expanded due to frictional heat, and sliding frictional force is increased by the expansion. As a result, the sliding portion is further overheated. In addition, when the sliding frictional force increases, pressing pressure is insufficient.

However, the technique disclosed in Japanese Laid-Open Patent Publication No. 07-245366 is for cooling the bending punch and the bending die, but cannot suppress the overheating of the sliding portion.

As such, it is difficult to suppress the overheating of the sliding portion of the press apparatus.

### SUMMARY

In one embodiment, there is provided a press apparatus including: a bolster; a lower die holder that is mounted on the bolster to which a lower die is to be provided; a guide post that is vertically provided in the lower die holder; a guide bush that slides along the guide post; an upper die holder that is fixed to the guide bush to which an upper die is to be provided; and a heat transfer accelerating portion that contacts the guide post and the bolster and accelerates the transfer of heat from the guide post to the bolster.

The press apparatus includes the heat transfer accelerating portion that contacts the guide post and the bolster and accelerates the transfer of heat from the guide post to the bolster. Therefore, it is possible to effectively transfer frictional heat generated from the sliding portion of the press apparatus, that is, the guide post and the guide bush to the bolster through the heat transfer accelerating portion. Therefore, it is possible to suppress the overheating of the sliding portion of the press apparatus.

In another embodiment, there is provided a method for manufacturing a semiconductor device including: pressing the semiconductor device using a semiconductor manufacturing apparatus that includes a bolster, a lower die holder that is mounted on the bolster to which a lower die is to be provided, a guide post that is vertically provided in the lower die holder, a guide bush that slides along the guide post, an upper die holder that is fixed to the guide bush to which an upper die is to be provided, and a heat transfer accelerating portion that contacts the guide post and the bolster and accelerates the transfer of heat from the guide post to the bolster, the upper and lower dies pressing the semiconductor device.

According to the invention, it is possible to suppress the overheating of the sliding portion of the press apparatus.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram illustrating a semiconductor manufacturing apparatus (press apparatus) according to a first embodiment and shows a state in which an upper die holder is disposed at a top dead point, in which the left half is a front view and the right half is a front cross-sectional view;

FIG. 2 is a diagram illustrating the semiconductor manufacturing apparatus (press apparatus) according to the first embodiment and shows a state in which the upper die holder is disposed at a bottom dead point, in which the left half is a front view and the right half is a front cross-sectional view;

FIG. 3A is a plan view illustrating an example of a semiconductor device manufactured by the semiconductor manufacturing apparatus according to the embodiment;

FIG. 3B is a cross-sectional view illustrating the semiconductor device taken along the line A-A of FIG. 3A;

FIGS. 4A to 4C are diagrams illustrating an example of the procedure of a method for manufacturing the semiconductor device according to the embodiment;

FIGS. 5A to 5C are diagrams illustrating another example of the procedure of the method for manufacturing the semiconductor device according to the embodiment;

FIG. 6 is a diagram illustrating a semiconductor manufacturing apparatus (press apparatus) according to a comparative example, in which the left half is a front view and the right half is a front cross-sectional view;

FIG. 7 is a diagram illustrating the relationship between a clearance between a guide post and a guide bush of the semiconductor manufacturing apparatus (press apparatus) according to the comparative example and a load when the guide bush slides along the guide post;

FIG. 8 is a diagram illustrating a semiconductor manufacturing apparatus (press apparatus) according to a second embodiment and shows a state in which an upper die holder is disposed at a top dead point, in which the left half is a front view and the right half is a front cross-sectional view;

FIG. 9 is a diagram illustrating the semiconductor manufacturing apparatus (press apparatus) according to the second embodiment and shows a state in which the upper die holder is disposed at a bottom dead point, in which the left half is a front view and the right half is a front cross-sectional view;

FIG. 10 is a block diagram illustrating an electronic circuit included in the semiconductor manufacturing apparatus (press apparatus) according to the second embodiment;

FIG. 11 is a block diagram illustrating a modification of the electronic circuit;

FIG. 12 is a block diagram illustrating the periphery of an electronic circuit included in a semiconductor manufacturing apparatus (press apparatus) according to a third embodiment; and

FIG. 13 is a block diagram illustrating the periphery of an electronic circuit included in a semiconductor manufacturing apparatus (press apparatus) according to a fourth embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention will be explained below, referring to the attached drawings. Note that any similar constituents will be given the same reference numerals or symbols in all drawings, and explanations therefor will not be repeated.

### First Embodiment

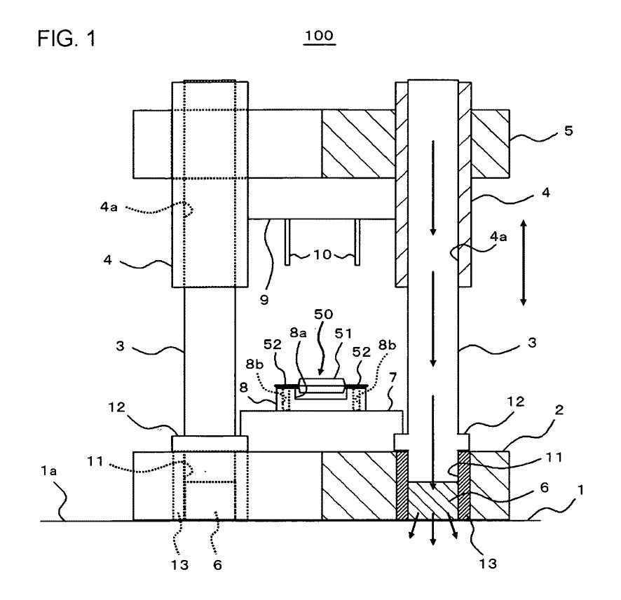

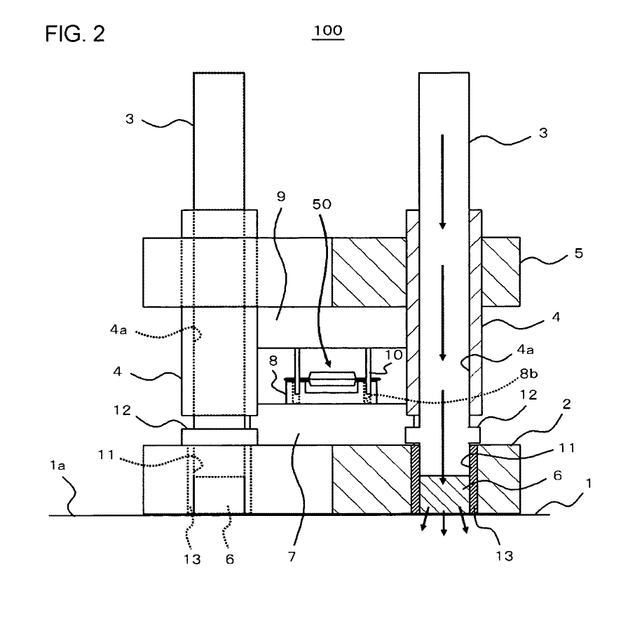

FIGS. 1 and 2 are diagrams illustrating a press apparatus 100 according to a first embodiment, in which the left half is a front view and the right half is a front cross-sectional view. FIG. 1 shows a state in which an upper die holder 5 is disposed at a top dead point, and FIG. 2 shows a state in which the upper die holder 5 is disposed at a bottom dead point.

The press apparatus 100 according to the first embodiment includes a bolster 1 and a lower die holder 2 that is mounted on the bolster 1 to which a lower die (for example, a die plate 7 and a die 8) is to be provided. The press apparatus 100 further includes guide posts 3 that are vertically provided in the lower die holder 2, guide bushes 4 that slide along the guide posts 3, and the upper die holder 5 that is fixed to the guide bushes 4 to which an upper die (for example, a punch plate 9 and a punch 10) is to be provided. The press apparatus 100 further includes heat transfer accelerating portions 6 that contact the guide posts 3 and the bolster 1 and accelerate the transfer of heat from the guide posts 3 to the bolster 1. Next, the press apparatus 100 will be described in detail.

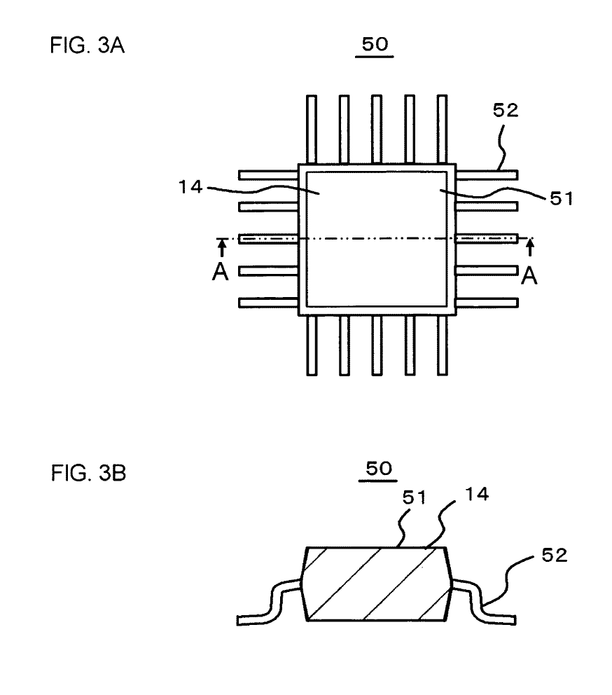

The press apparatus 100 according to the first embodiment is, for example, a semiconductor manufacturing apparatus and presses a semiconductor device 50, which is a processing object. As shown in FIGS. 3A and 3B, the semiconductor device 50 includes a main portion 51 that is sealed by a encapsulating resin 14 and leads 52 that project from the main portion 51 to the outside.

As shown in FIGS. 1 and 2, the bolster 1 includes a mounting portion 1a on which the lower die holder 2 is mounted. The mounting portion 1a has, for example, a plate shape. The mounting portion 1a of the bolster 1 has a horizontal upper surface. A portion (a portion that is not covered with the lower die holder 2) of the upper surface of the mounting portion 1a of the bolster 1 is exposed to air and serves as a heat dissipation surface.

The lower die holder 2 has, for example, a plate shape and is horizontally fixed on the mounting portion 1a. For example, four fitting holes 11 are formed in the lower die holder 2 so as to pass through the front-back both sides of the lower die holder 2.

The die plate 7 and the die 8 are provided as the lower die on the upper surface of the lower die holder 2. The die plate 7 has, for example, a plate shape and is horizontally fixed on the lower die holder 2. The die 8 is fixed on the die plate 7. A concave portion 8a in which the main portion 51 of the semiconductor device 50 is arranged and punch holes 8b into which punches 10 are fitted are formed in the upper surface of the die 8. The number of punch holes 8b corresponds to the number of punches 10. When the semiconductor device 50 is pressed, for example, the leads 52 of the semiconductor device 50 are mounted on the upper surface of a portion of the die 8 which is disposed outside the concave portion 8a, and the main portion 51 is suspended in the concave portion 8a.

The guide posts 3 have a columnar shape (for example, a cylindrical shape) and are arranged, for example, at four corners of the lower die holder 2 in a plan view. FIGS. 1 and 2 show two front guide posts 3 among the four guide posts 3, and two more guide posts 3 are also disposed at the back of the two front guide posts 3. The lower end of each of the guide posts 3 is fitted to the corresponding fitting hole 11 from the upper side. In this way, each guide post 3 is vertically provided in the lower die holder 2. A flange portion 12 that comes into contact with, for example, the upper edge of the fitting hole 11 is formed at a lower part of the guide post 3. The flange portion 12 makes it possible to stabilize the position of the guide post 3 and set and maintain the amount of fitting of the guide post 3 to the fitting hole 11 with high accuracy.

Each guide post 3 is inserted into the guide bush 4. That is, an insertion hole 4a is formed in the guide bush 4, and the guide post 3 is inserted into the insertion hole 4a. A small clearance is set between the inner circumference of the insertion hole 4a and the outer circumference of the guide post 3 such that the guide bush 4 can slide along the guide post 3 in the vertical direction.

The upper die holder 5 has, for example, a plate shape and is horizontally held by the four guide bushes 4. A plate-shaped punch plate 9 is horizontally fixed on the lower surface of the upper die holder 5. Four punches 10 are fixed to the lower surface of the punch plate 9 so as to vertically fall to the corresponding four side surfaces of the semiconductor device 50. The punches 10 are arranged so as to face the punch holes 8b of the die 8. The upper die holder 5 is made of, for example, a metal material.

The upper die holder 5 is moved up and down between the top dead point position shown in FIG. 1 and the bottom dead point position shown in FIG. 2 by pressing force applied by a driving source (not shown). With the moving-up and down of the upper die holder 5, the guide bushes 4, the punch plate 9, and the punches 10 fixed to the upper die holder 5 are moved up and down. At the bottom dead point position shown in FIG. 2, each punch 10 is fitted to the corresponding punch hole 8b. The punches 10 press (for example, cut or bend) the leads 52 of the semiconductor device 50 in cooperation with the die 8 while moving from the position shown in FIG. 1 to the position shown in FIG. 2. In addition, each punch 10 collectively processes a plurality of leads 52 protruding from the corresponding side surface of the semiconductor device 50.

The heat transfer accelerating portion 6 accelerates the transfer of heat from the guide post 3 to the bolster 1, as compared to a case in which the guide post 3 comes into direct contact with the bolster 1. In the first embodiment, the heat transfer accelerating portion 6 includes a first heat transfer member made of a material having a thermal conductivity higher than that of the guide post 3. Therefore, the transfer efficiency of heat from the guide post 3 to the bolster 1 is improved, as compared to the case in which the guide post 3 comes into direct contact with the bolster 1.

It is more preferable that the heat transfer accelerating portion 6 be made of a material having a thermal conductivity higher than that of the lower die holder 2. In this case, it is possible to suppress heat from flowing from the heat transfer accelerating portion 6 to the lower die holder 2 such that heat is less likely to be stored in the lower die holder 2. Therefore, it is possible to suppress the strain deformation of the lower die holder 2 due to thermal expansion.

It is preferable that the heat transfer accelerating portion 6 be made of a metal material with a thermal conductivity of equal to or more than 300 W/(m·° C.). Specifically, the heat transfer accelerating portion 6 may be made of, for example, copper, silver, or gold, an alloy including at least one of them, or an alloy including at least one of them as a main component (for example, including 50 wt % or more of at least one of them). Alternatively, the heat transfer accelerating portion 6 may be made of aluminum, an aluminum alloy, or an alloy including aluminum as a main component (for example, 50 wt % or more of aluminum).

The heat transfer accelerating portion 6 is provided for each guide post 3. The heat transfer accelerating portion 6 has, for example, a columnar shape (for example, a cylindrical shape) or a plate shape (for example, a disk shape), and is interposed between the lower end surface of each guide post 3 and the upper surface of the bolster 1, and comes into contact with the lower end surface of each guide post 3 and the upper surface of the bolster 1. The lower end surface of the guide post 3, the upper and lower surfaces of the heat transfer accelerating portion 6, and the upper surface of the bolster 1 have low surface roughness and are smooth.

The contact area between the lower end surface of the guide post 3 and the upper surface of the heat transfer accelerating portion 6 and the contact area between the lower surface of the heat transfer accelerating portion 6 and the upper surface of the bolster 1 are substantially equal to the cross-sectional area of the fitting hole 11. It is more preferable that each of the contact areas be equal to or more than, for example, 100 mm² and more preferably, equal to or more than 400 mm².

For example, the heat transfer accelerating portion 6 is arranged (specifically, for example, fitted) inside the fitting hole 11 and is buried in the lower die holder 2. In other words, the heat transfer accelerating portion 6 is covered with a portion of the press apparatus 100 other than the heat transfer accelerating portion 6 and is not exposed from the outer surface of the press apparatus 100. In this way, the heating of the atmosphere by the heat transfer accelerating portion 6 is suppressed.

A low thermal conducting portion 13 is provided in the periphery of the fitting hole 11 in the lower die holder 2 and is made of a material with a thermal conductivity lower than that of a peripheral portion of low thermal conducting portion 13. The low thermal conducting portion 13 surrounds the lower end of the guide post 3 and the heat transfer accelerating portion 6. Therefore, the flow of heat from the guide post 3 and the heat transfer accelerating portion 6 to the lower die holder 2 is suppressed.

It is preferable that the low thermal conducting portion 13 be made of a metal material with a thermal conductivity equal to or less than 30 W/(m·° C.). For example, the low thermal conducting portion 13 may be made of stainless steel. Among the metal materials, in particularly, austenite-based stainless steel is preferable since it has low thermal conductivity. The austenite-based stainless steel has a thermal conductivity of, for example, less than 20 W/(m·° C.).

The bolster 1 having a portion of the upper surface serving as a heat dissipation surface is made of a steel material, such as SS400 which is rolled steel for a general structure or S50C which is carbon steel for a mechanical structure.

For the upper surface of the mounting portion 1a of the bolster 1, it is preferable that the ratio of the area of a region covered with the lower die holder 2 to the area of a region which is exposed to air without being covered with the lower die holder 2 be 1:n (n is equal to or greater than 1) in terms of heat dissipation.

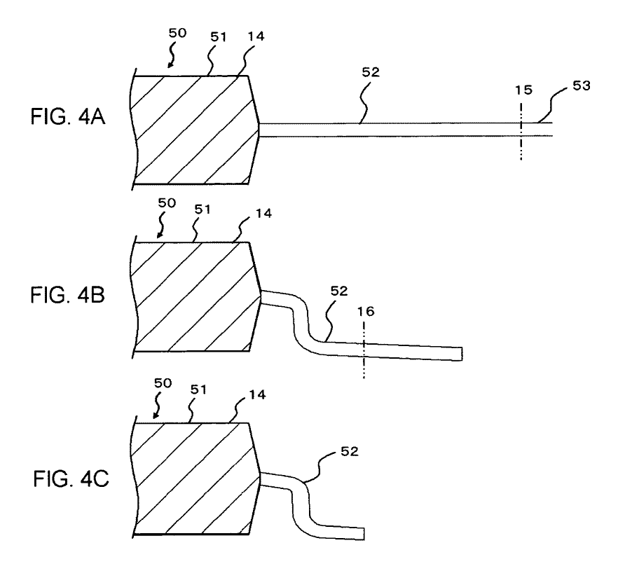

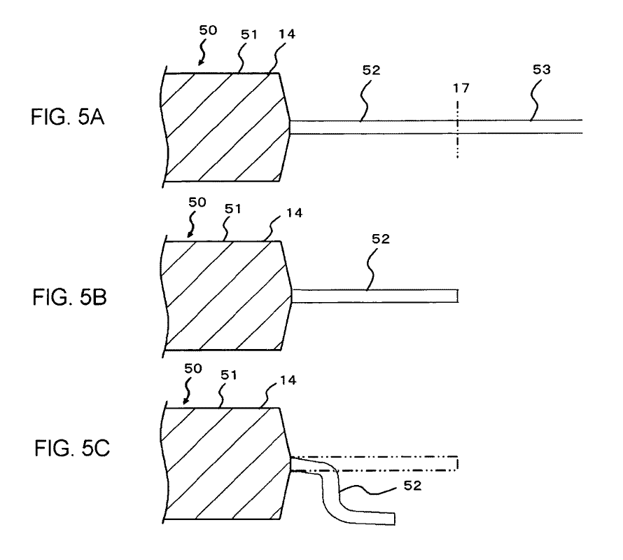

Next, a method for manufacturing the semiconductor device according to the first embodiment will be described. FIGS. 3A and 3B are diagrams illustrating the semiconductor device 50 manufactured by the manufacturing method. FIG. 3A is a plan view and FIG. 3B is a cross-sectional view taken along the line A-A of FIG. 3A. FIGS. 4A to 4C are diagrams illustrating an example of the procedure of the manufacturing method, and FIGS. 5A to 5C are diagrams illustrating another example of the procedure of the manufacturing method.

The method for manufacturing the semiconductor device according to the first embodiment includes a process of pressing the semiconductor device 50 using a semiconductor manufacturing apparatus (press apparatus 100) including the bolster 1, the lower die holder 2 that is mounted on the bolster 1 to which the lower die (for example, the die plate 7 and the die 8) is to be provided, the guide posts 3 that are vertically provided in the lower die holder 2, the guide bushes 4 that slide along the guide posts 3, the upper die holder 5 that are fixed to the guide bushes 4 to which the upper die (for example, the punch plate 9 and the punch 10) is to be provided, and the heat transfer accelerating portions 6 that contact the guide posts 3 and the bolster 1 and accelerate the transfer of heat from the guide posts 3 to the bolster 1. The upper die and the lower die press the semiconductor device 50. Next, the manufacturing method will be described in detail.

As shown in FIGS. 3A and 3B, the main portion 51 of the semiconductor device 50 includes, for example, the encapsulating resin 14, a semiconductor chip (not shown) provided in the encapsulating resin 14, and a die pad (not shown). A plurality of leads 52 protrudes from the side surface of the encapsulating resin 14. The lead 52 has a thickness of, for example, 0.125 mm to 0.150 mm and a width of about 0.2 mm. A plating film is coated on the upper, lower, and side surfaces (except a lead cut surface) of the lead 52. The lead 52 has a thickness of about 0.125 mm to 0.180 mm including the thickness of the plating film.

First, a semiconductor chip (not shown) is mounted and bonded to a die pad (not shown) of a lead frame (the entire lead frame is not shown), and the semiconductor chip and the lead 52 are wire-bonded by bonding wires (not shown). Then, the semiconductor chip and the lead frame are encapsulated by the encapsulating resin 14 (FIGS. 3A and 3B) such that a portion of the lead 52 protrudes from the encapsulating resin 14 (FIGS. 3A and 3B). Then, the burr of the encapsulating resin 14 is removed. When a lead frame that is not subjected to exterior processing in advance is used, an exterior plating process is performed on the lead frame.

Then, the semiconductor device 50 is cut off from the lead frame 53 (see FIG. 4A; the entire lead frame 53 is not shown) and a process of forming the leads 52 is performed.

Specifically, for example, first, the lead frame 53 is cut at a cutting position 15 such that the lead 52 is elongated as shown in FIG. 4A. In this way, the semiconductor device 50 is cut off from the lead frame 53. Then, the lead 52 is bent downward as shown in FIG. 4B to have a predetermined gullwing shape. Then, as shown in FIG. 4C, the lead 52 is cut at a cutting position 16 to have specified dimensions.

Alternatively, first, as shown in FIG. 5A, the lead frame 53 is cut at a cutting position 17 such that the lead 52 has specified dimensions. In this way, the semiconductor device 50 is cut off from the lead frame 53 (FIG. 5B). Then, as shown in FIG. 5C, the lead 52 is bent downward to have a predetermined gullwing shape.

The lead 52 is processed by the press apparatus 100 (semiconductor manufacturing apparatus) according to the first embodiment. The press apparatus 100 may be used in any one of a process of cutting off the semiconductor device 50 from the lead frame (FIGS. 4A and 5B), a processing of bending the lead 52 in a gullwing shape (FIGS. 4B and 5C), and a process of cutting the gullwing-shaped lead 52 (FIG. 4B).

As such, the press apparatus 100 is used to cut or bend the lead 52. However, as the processing conditions of the press apparatus 100, the cutting position or bending position of the lead 52 is within an error range of, for example, several microns. Therefore, it is important to position the punch 10 and the die 8 with high accuracy and the clearance between the guide post 3 and the guide bush 4 is set to a very small value. Under these conditions, when the press speed increases and the press apparatus is continuously operated for a long time in order to improve productivity, the guide bush 4 and the guide post 3 are overheated and expanded due to frictional heat generated from a sliding portion between the guidepost 3 and the guide bush 4. As a result, sliding frictional force increases and pressing pressure is insufficient.

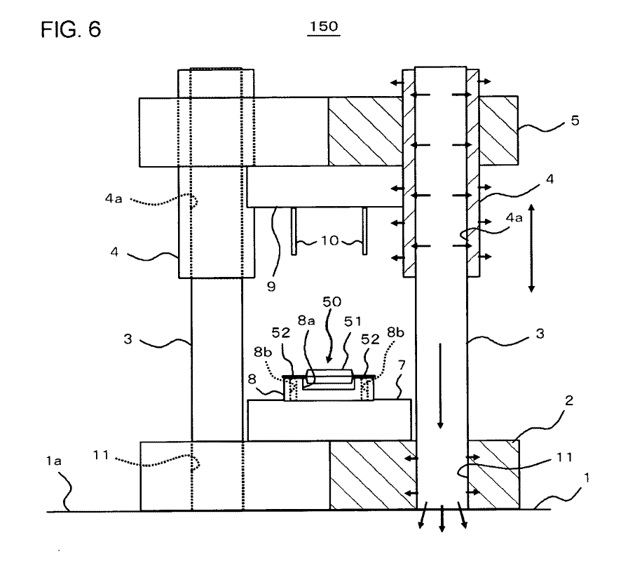

FIG. 6 is a diagram illustrating a press apparatus 150 according to a comparative example, in which the left half is a front view and the right half is a front cross-sectional view. The press apparatus 150 has the same structure as the press apparatus 100 according to the first embodiment except that it does not include the heat transfer accelerating portion 6 and the low thermal conducting portion 13 and the lower end surface of the guide post 3 comes into direct contact with the upper surface of the bolster 1.

As shown in FIG. 6, the guide bush 4 has an outer circumferential surface that is exposed from the upper die holder 5 and contacts air. Therefore, heat is constantly dissipated to air. Heat radiated from the guide post 3 is mainly dissipated to the lower die holder 2 and the bolster 1. In recent years, a press apparatus has come into widespread use in which grease that is fed less frequently than lubricating oil is used as a lubricant applied onto a sliding surface between the guide post 3 and the guide bush 4. However, since the grease has a low heat dissipation performance, the guide post 3 is gradually overheated and expanded due to frictional heat with an increase in the operating time of the press apparatus 150 in which the outer circumferential surface of the guide post 3 is covered with the grease.

An example of the conditions of the press apparatus 150 in which the clearance between the guide post 3 and the guide bush 4 is set to a very small value for high-accuracy positioning is as follows:
A clearance C between the guide post 3 and the guide bush 4: 2.5 μm;
A material forming the guide post 3: bearing steel (SUJ material=high-carbon steel);
The linear expansion coefficient α of the high-carbon steel forming the guide post 3: 10.8×10⁻⁶/° C.;
The volume expansion coefficient β of the high-carbon steel forming the guide post 3=3α: 32.4×10⁻⁶/° C.;
The diameter R of the guide post 3: 23 mm;
The length L of the guide post 3: 210 mm; and
The volume V of the guide post 3=(π×(R/2)²×L): 87250 mm³.

The clearance C, the diameter R, the length L, and the volume V are values when the management temperature Ts of a room in which the press apparatus 150 is arranged is 25° C.

Under these conditions, when the temperature of the guide post 3 is increased by 1° C., the clearance C between the guidepost 3 and the guide bush 4 is theoretically reduced by 0.19 μm.

Therefore, theoretically, the temperature at which the clearance C is zero is 38.16° C. When the clearance C is zero, tribologically, sliding friction between the guide post 3 and the guide bush 4 is friction in a boundary lubrication region (region in which sliding does not occur), and a lubricant between the guide post 3 and the guide bush 4 has a film thickness equal to or less than the surface roughness of the sliding surface between the guide post 3 and the guide bush 4. As a result, press sliding cannot occur.

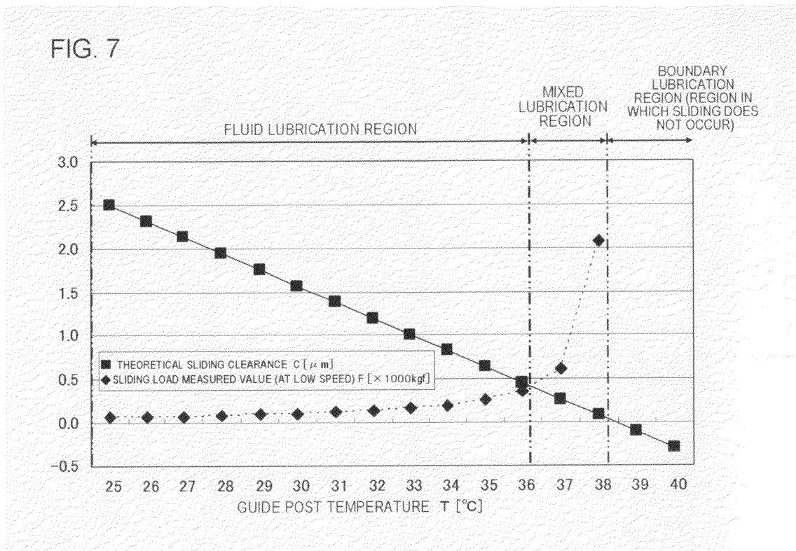

FIG. 7 is a diagram illustrating the relationship between the theoretical clearance C between the guide post 3 and the guide bush 4 of the press apparatus 150 shown in FIG. 6 and the measured value of a load (sliding load) when the guide bush 4 slides along the guide post 3. In FIG. 7, the horizontal axis is the temperature of the guide post 3. The measured value of FIG. 7 is obtained by continuously operating the press apparatus 150 to gradually increase the temperature of the guide post 3. Grease is used as the lubricant and the sliding load is measured during a low-speed pressing operation in which strong frictional force is applied due to thixotropy (pressing speed 5 mm/s).

As shown in FIG. 7, the theoretical clearance C varies linearly with a variation in temperature. The sliding load varies substantially linearly from a sliding load of 60 kgf at 25° C. to a sliding load of 200 kgf at 34° C. However, the sliding load rapidly increases from around 35° C. so as to draw a quadratic curve with an increase in temperature. During the continuous operation of the press apparatus 150, there is a vicious cycle in which, as the sliding load increases, frictional heat generated from the sliding portion increases, which results in an increase in the sliding load. An inexpensive air-type press unit can be used to perform press sliding up to a sliding load of about 360 kgf at 36° C. However, at a sliding load of 610 kgf at 37° C., a driving source capable of outputting a driving force of several thousands of kgf, such as a motor type or a hydraulic type, is needed, which results in an increase in the cost of the press apparatus 150.

In practice, since frictional heat generated from the sliding portion between the guide bush 4 and the guide post 3 is also transferred to the guide bush 4, the diameter of the guide bush 4 is likely to increase with an increase in temperature. However, as described above, the guide post 3 is covered with grease with a low heat dissipation performance. In addition, while heat of the guide bush 4 is smoothly dissipated to the upper die holder 5 made of, for example, a metal material, heat of the guide post 3 is mainly dissipated from the lower end of the guide post 3 to the lower die holder 2 and the bolster 1. Therefore, in the press apparatus 150 shown in FIG. 6, the heat dissipation performance of the guide post 3 is low and the temperature of the guide post 3 is higher than that of the guide bush 4. As a result, it is considered that the sliding friction and sliding load of the guide post 3 and the guide bush 4 increase with an increase in temperature.

In contrast, as shown in FIGS. 1 and 2, the press apparatus 100 according to the first embodiment includes the heat transfer accelerating portion 6 that contacts the guide post 3 and the bolster 1 and accelerates the transfer of heat from the guide post 3 to the bolster 1. Therefore, it is possible to effectively transfer frictional heat generated from the sliding portion of the press apparatus 100, that is, the guide post 3 and the guide bush 4, to the bolster 1 through the heat transfer accelerating portion 6. It is possible to suppress the overheating of the sliding portion of the press apparatus 100. As a result, it is possible to obtain a stable and high-reliability sliding state of the sliding portion of the press apparatus 100 while maintaining a uniform clearance between the guide post 3 and the guide bush 4 and positioning the punch 10 and the die 8 with high accuracy.

The bolster 1 serves as a heat dissipating portion that dissipates heat transferred from the sliding portion through the heat transfer accelerating portion 6. Since the lower die holder 2 is mounted on the bolster 1, it is premised that the bolster 1 has, for example, high abrasion resistance or high rigidity (high Young's modulus). When the bolster 1 is made of a steel material, such as SS400 or S50C, it is possible to improve the abrasion resistance or rigidity of the bolster 1. In addition, these steel materials have characteristics of relatively low thermal conductivity and relatively high heat capacity. The thermal conductivity of copper is more than that of steel, and the heat capacity of steel is more than that of copper. Therefore, in particular, when the heat transfer accelerating portion 6 is made of copper, the transfer efficiency of heat from the heat transfer accelerating portion 6 to the bolster 1 is very high. When the bolster 1 is made of steel material, the thermal conductivity of the bolster 1 is, for example, equal to or more than 50 W/(m·° C.) and equal to or less than 100 W/(m·° C.). However, the bolster 1 may be made of any material having a thermal conductivity that is higher than that of the low thermal conducting portion 13 (for example, austenite-based stainless steel) surrounding the lower end of the guide post 3 and is lower than that of the heat transfer accelerating portion 6. Therefore, for example, the bolster 1 may be made of a material having a thermal conductivity equal to or more than 50 W/(m·° C.) and equal to or less than 200 W/(m·° C.).

In general, the mounting portion la of the bolster 1 has a plane size of 1000 mm by 1000 mm and a thickness of more than 50 mm. Therefore, the mounting portion la has sufficient heat capacity with respect to the amount of heat transferred from the guide post 3 through the heat transfer accelerating portion 6. It is possible to obtain an excellent heat dissipation and cooling effect from the heat dissipation surface of the bolster 1. Specifically, for example, when the bolster 1 is made of a steel material, the weight of the bolster 1 is set equal to or more than 60 kg (the volume of the bolster 1 is set equal to or more than 7,500,000 mm³). In this case, it is possible to reduce an increase in the temperature of the guide post 3 to 0.1 degree or less in the structure shown in FIGS. 1 and 2, even under the conditions that an increase in the temperature of the guide post 3 is 20 degrees in the structure shown in FIG. 6.

According to the first embodiment, the press apparatus 100 includes the heat transfer accelerating portion 6 that contacts the guide post 3 and the bolster 1 and accelerates the transfer of heat from the guide post 3 to the bolster 1. Therefore, it is possible to effectively transfer frictional heat generated from the sliding portion of the press apparatus 100, that is, the guide post 3 and the guide bush 4, to the bolster 1 through the heat transfer accelerating portion 6. It is possible to suppress the overheating of the sliding portion of the press apparatus 100. In addition, the very high heat capacity of the bolster 1 on which the lower die holder 2 is mounted and the bolster 1 is used as a heat dissipating portion. In this way, it is possible to obtain an excellent heat dissipation and cooling effect and stably perform temperature control.

In addition, since the clearance between the guidepost 3 and the guide bush 4 can be constantly maintained, it is possible to maintain the relative positional relationship between the upper die and the lower die (for example, the relative position between the punch 10 and the die 8) and maintain the pressing load to be constant. Since the pressing load can be constantly maintained, it is possible to use an inexpensive driving source capable of responding to a low load, such as an air cylinder type, not an expensive press unit for responding to a load variation, such as a hydraulic type or a motor type.

For example, in the automobile industry, a computerized technique including hybrid cars has been rapidly developed. In particular, for example, in in-vehicle semiconductor devices requiring high connection reliability, high accuracy and stable quality are required for the bent shape or cut surface of the lead 52, which is a mounting portion. According to the first embodiment, in the press apparatus 100 in which the clearance between the guide post 3 and the guide bush 4 is very small in order to perform the high-accuracy process, it is also possible to suppress the heating of the sliding portion.

The heat transfer accelerating portion 6 is made of the first heat transfer member, which is a material having a thermal conductivity higher than that of the guide post 3, and the first heat transfer member (that is, the heat transfer accelerating portion 6) contacts the guide post 3 and the bolster 1. Therefore, it is possible to improve the transfer efficiency of heat from the guide post 3 to the bolster 1, as compared to the structure in which the guide post 3 comes into direct contact with the bolster 1.

In addition, the first heat transfer member (that is, the heat transfer accelerating portion 6) is made of a material having a thermal conductivity higher than that of the lower die holder 2. Therefore, it is possible to suppress the flow of heat from the heat transfer accelerating portion 6 to the lower die holder 2 and thus suppress the strain deformation of the lower die holder 2 due to thermal expansion.

The heat transfer accelerating portion 6 is covered with a portion of the press apparatus 100 except for the heat transfer accelerating portion 6 and is not exposed from the outer surface of the press apparatus 100. Specifically, the fitting hole 11 to which the lower end of the guide post 3 and the heat transfer accelerating portion 6 are fitted is formed in the lower die holder 2, and the lower end of the guide post 3 is fitted to the fitting hole 11 such that the guide post 3 is vertically provided in the lower die holder 2. The heat transfer accelerating portion 6 is interposed between the lower end of the guide post 3 and the upper surface of the bolster 1 in the fitting hole 11. Therefore, it is possible to suppress the heating of the atmosphere due to the heat transfer accelerating portion 6.

A portion (low thermal conducting portion 13) of the lower die holder 2 disposed in the circumference of the fitting hole 11 is made of a material having a thermal conductivity lower than that of a peripheral portion of the low thermal conducting portion 13. Therefore, it is possible to suppress the flow of heat from the guide post 3 and the heat transfer accelerating portion 6 to the lower die holder 2.

In the technique disclosed in Japanese Laid-Open Patent Publication No. 07-245366, the Peltier element and the heat sink are provided in the die and the outer circumference thereof is covered with the die. Therefore, heat is stored in the die and it is difficult to sufficiently dissipate heat. The cooling effect of the bending punch and the bending die is damaged. Therefore, it is considered that, even when the technique disclosed in Japanese Laid-Open Patent Publication No. 07-245366 is diverted to the cooling of the sliding portion, it is difficult to sufficiently cool the sliding portion. In addition, the Peltier element dissipates heat generated by the driving of the Peltier element as well as heat absorbed on the heat absorption side from the heating side. Therefore, the amount of heat stored in the die further increases.

In the technique disclosed in Japanese Laid-Open Patent Publication No. 07-245366, when the outer circumference of the arrangement space of the Peltier element is covered with a heat isolation member, the temperature of the Peltier element is increased by the dissipated heat. As a result, cooling capacity is reduced and a destructive failure is likely to occur in the Peltier element. When the outer circumference is not covered with the heat isolation member, heat in the die is transferred and strain deformation occurs in the die due to local thermal expansion, which causes the deterioration of processing accuracy.

In addition, the technique disclosed in Japanese Laid-Open Patent Publication No. 07-245366 requires a relative large charging device requiring an external power source, such as a current control unit, and a large number of wiring lines involved in the charging device, in addition to the press apparatus that processes a processing object. Therefore, when the die is replaced, it takes a lot of time and a large number of processes to, for example, remove, install, and adjust the charging device in addition to the replacement of the die.

### Second Embodiment

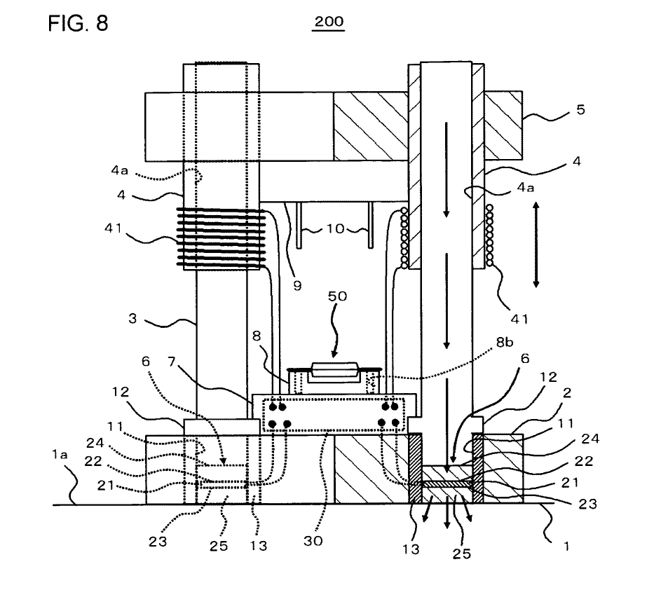

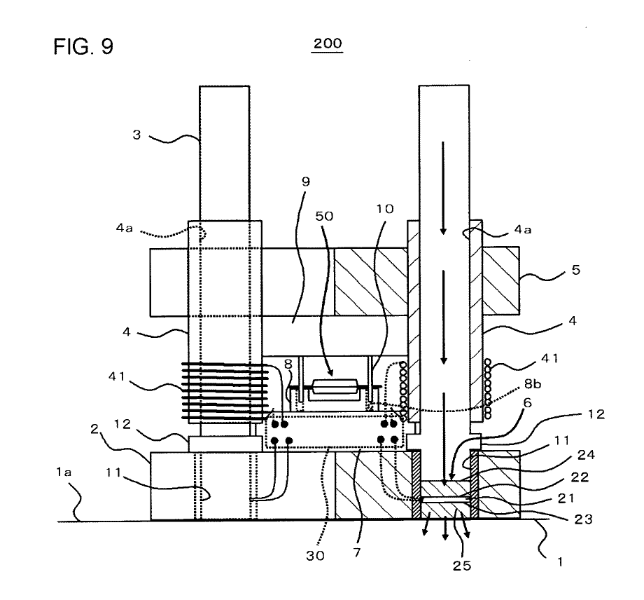

FIGS. 8 and 9 are diagrams illustrating a press apparatus 200 according to a second embodiment, in which the left half is a front view and the right half is a front cross-sectional view. FIG. 8 shows a state in which an upper die holder 5 is disposed at a top dead point and FIG. 9 shows a state in which the upper die holder 5 is disposed at a bottom dead point. The press apparatus 200 according to the second embodiment has the same structure as the press apparatus 100 according to the first embodiment except for the following points.

In the second embodiment, each heat transfer accelerating portion 6 includes a Peltier element 21 having a heat absorbing portion 22 and a heat dissipating portion 23. The Peltier element 21 has, for example, a thin flat disk shape and includes the heat absorbing portion (heat absorbing surface) 22 that absorbs heat on one surface and the heat dissipating portion (heat dissipation surface) 23 that dissipates heat on the other surface. In the Peltier element 21, the heat absorbing portion 22 faces the guide post 3 (upper side) and the heat dissipating portion 23 faces the bolster 1 (lower side).

In the second embodiment, each heat transfer accelerating portion 6 includes second and third heat transfer members 24 and 25 made of a material having a thermal conductivity higher than that of the guide post 3. The second heat transfer member 24 contacts the guide post 3 and the heat absorbing portion 22 of the Peltier element 21, and the third heat transfer member 25 contacts the heat dissipating portion 23 of the Peltier element 21 and the bolster 1.

Specifically, the second heat transfer member 24, the

Peltier element 21, and the third heat transfer member 25 are arranged in the fitting hole 11. The second heat transfer member 24 has, for example, a plate shape (for example, a disk shape) or a columnar shape (for example, a cylindrical shape), is interposed between the lower end surface of the guide post 3 and the upper surface of the Peltier element 21, and comes into contact with the lower end surface of the guide post 3 and the upper surface of the Peltier element 21. Similarly, the third heat transfer member 25 has, for example, a plate shape (for example, a disk shape) or a columnar shape (for example, a cylindrical shape), is interposed between the lower surface of the Peltier element 21 and the upper surface of the bolster 1, and comes into contact with the lower surface of the Peltier element 21 and the upper surface of the bolster 1. The lower end surface of the guide post 3, the upper and lower surfaces of the second heat transfer member 24, the upper and lower surfaces of the Peltier element 21, and the upper and lower surfaces of the third heat transfer member 25, the upper surface of the bolster 1 have low surface roughness and are smooth.

The second and third heat transfer members 24 and 25 are made of the same material as that forming the first heat transfer member according to the first embodiment. Similar to the first heat transfer member, it is preferable that the second and third heat transfer members 24 and 25 be made of a material having a thermal conductivity higher than that of the lower die holder 2.

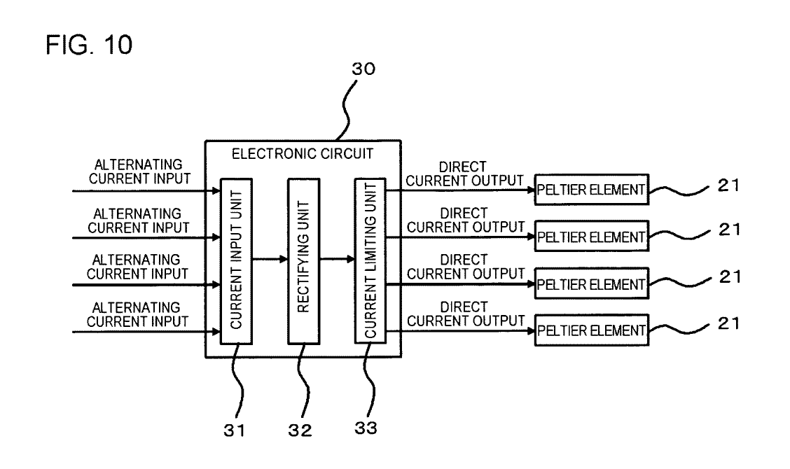

The press apparatus 200 further includes an electronic circuit 30 that supplies a driving current to the Peltier element 21. FIG. 10 is a block diagram illustrating the structure of the electronic circuit 30.

As shown in FIG. 10, the electronic circuit 30 includes, for example, a current input unit 31 that receives an alternating current, a rectifying unit 32 that converts the alternating current input to the current input unit 31 into a direct current, and a current limiting unit 33 that limits a current input to the Peltier element 21 to a predetermined upper limit. The current limiting unit 33 outputs only a current component equal to or less than the predetermined upper limit among the direct current components output from the rectifying unit 32 as a driving current to the Peltier element 21. The Peltier element 21 is driven by the driving current input from the current limiting unit 33 of the electronic circuit 30 such that the heat absorbing portion 22 performs a heat absorption operation and the heat dissipating portion 23 performs a heat dissipation operation. The electronic circuit 30 is provided in, for example, the die plate 7.

The press apparatus 200 further includes a power generating unit that generates power using the relative movement between the guide post 3 and the guide bush 4. The Peltier element 21 is driven by power generated by the power generating unit.

The power generating unit includes, for example, the guide post 3, the guide bush 4, and a coil 41 that is wound around one of the guide post 3 and the guide bush 4, and the other one of the guide post 3 and the guide bush 4 is made of a magnetized magnetic material. When the guide post 3 and the guide bush 4 are moved relative to each other, a current is generated in the coil 41 by electromagnetic induction.

Specifically, the coil 41 is wound around each guide bush 4, and each guide post 3 is made of a magnetized magnetic material. For example, the magnetization range, magnetized portion, and amount of magnetization of the guide post 3, the diameter and number of windings of the coil 41, and the winding range of the coil 41 with respect to the guide bush 4 are appropriately set depending on the control setting temperature of the guide post 3 and the rating of the Peltier element 21.

Both ends of the coil 41 wound around each guide bush 4 are connected to the current input unit 31 of the electronic circuit 30, and an alternating current generated in each coil 41 is input to the current input unit 31. Therefore, the current input unit 31 includes, for example, four pairs of input terminals to which the current generated in the coils 41 is input. The current limiting unit 33 outputs a direct current to the Peltier element 21 of each heat transfer accelerating portion 6. Therefore, the current limiting unit 33 includes, for example, four pairs of output terminals from which a current is output to the Peltier elements 21.

In the second embodiment, similar to the first embodiment, since the guide post 3 has a flange portion 12, it is possible to stabilize the position of the guide post 3 and set and maintain the amount of fitting of the guide post 3 to the fitting hole 11 with high accuracy. In addition, it is possible to suppress an impact or load applied to the guide post 3 from being transmitted to the Peltier element 21.

In the second embodiment, similar to the first embodiment, since the low thermal conducting portion 13 is provided in the periphery of the fitting hole 11 in the lower die holder 2, the flow of heat from the guide post 3 and the heat transfer accelerating portion 6 (the second heat transfer member 24, the Peltier element 21, and the third heat transfer member 25) to the lower die holder 2 is suppressed.

When a portion of the press apparatus 200 is adversely affected by the magnetic field generated in the coil 41 due to electromagnetic induction, it is preferable that the portion be made of a non-magnetic material or the portion be surrounded by a non-magnetic material to be electromagnetically shielded.

Next, the operation of the second embodiment will be described.

In the second embodiment, during the driving of the press apparatus 200, when the guide bush 4 is moved relative to each guide post 3, an alternating current is generated in the coil 41 wound around each guide bush 4 by electromagnetic induction. The alternating current is input to the rectifying unit 32 through the current input unit 31 of the electronic circuit 30 and is then converted into a direct current by the rectifying unit 32. The direct current is input to the current limiting unit 33 and the current limiting unit 33 limits the current value to a predetermined upper limit or less. The current is output as a driving current from the current limiting unit 33 to the Peltier element 21 of each heat transfer accelerating portion 6.

When the driving current is input to the Peltier element 21 of each heat transfer accelerating portion 6, the heat absorbing portion 22 performs the heat absorption operation and the heat dissipating portion 23 performs the heat dissipation operation. Therefore, heat transferred from the guidepost 3 to the heat absorbing portion 22 through the second heat transfer member 24 is smoothly transmitted from the heat absorbing portion 22 to the heat dissipating portion 23 and is then transferred to the bolster 1 through the third heat transfer member 25.

The driving current of the Peltier element 21 is limited by the current limiting unit 33. Therefore, the supercooling of the heat absorbing portion 22 is suppressed and the occurrence of dew condensation in, for example, a lower part of the guide post 3 is suppressed. When an excessively large amount of current is supplied to the Peltier element 21, the amount of heat generated from the Peltier element 21 increases, which may cause a reduction in the cooling effect of the guide post 3. However, since the driving current is limited by the current limiting unit 33, it is possible to suppress the reduction in the cooling effect.

It is possible to adjust the magnitude of the cooling effect of the guide post 3 by the Peltier element 21 by appropriately setting the upper limit of the current limited by the current limiting unit 33. In the press apparatus 200 in which the clearance between the guide post 3 and the guide bush 4 is set to a very small value in order to perform positioning with high accuracy, it is preferable to control the temperature of the guide post 3 in the range of, for example, 25° C. to 30° C. As can be seen from the relationship between the clearance C and the sliding load shown in FIG. 7, in the temperature range of 25° C. to 30° C. of the guide post 3, it is possible to reduce the sliding load to 100 kgf or less while maintaining high-accuracy positioning and thus achieve an ideal pressing operation. Therefore, it is preferable to set the upper limit of the current limited by the current limiting unit 33 such that the temperature of the guide post 3 can be controlled in the range of, for example, 25° C. to 30° C.

The second embodiment in which the driving current of the Peltier element 21 is obtained by power generated by the relative movement between the guide post 3 and the guide bush 4 has the following advantages.

That is, when the press apparatus 200 is not driven (when the guide post 3 and the guide bush 4 are not moved relative to each other), the amount of power generated and the amount of heat generated by the friction between the guide post 3 and the guide bush 4 are both zero. Therefore, the Peltier element 21 is not driven and the cooling of the guide post 3 by the Peltier element 21 is not performed. There is no increase in the temperature of the guide post 3 due to friction.

On the other hand, as the duration of the relative movement between the guide post 3 and the guide bush 4 increases or the relative movement speed increases, the amount of heat generated by the friction between the guide post 3 and the guide bush 4 increases and the amount of power generated also increases. Therefore, the cooling effect of the guide post 3 by the Peltier element 21 increases. That is, the autonomous temperature adjusting operation makes it possible to slowly increase the temperature of the guidepost 3 (reduce a temperature variation).

According to the second embodiment, the heat transfer accelerating portion 6 includes the Peltier element 21 having the heat absorbing portion 22 and the heat dissipating portion 23. The heat absorbing portion 22 of the Peltier element 21 is arranged so as to face the guide post 3 and the heat dissipating portion 23 is arranged so as to face the bolster 1. Therefore, it is possible to transfer heat from the guide post 3 to the bolster 1, that is, to cool the guide post 3 by driving the Peltier element 21.

The heat transfer accelerating portion 6 includes the second and third heat transfer members 24 and 25 made of a material having a thermal conductivity higher than that of the guide post 3. The second heat transfer member 24 contacts the guide post 3 and the heat absorbing portion 22 of the Peltier element 21 and the third heat transfer member 25 contacts the heat dissipating portion 23 of the Peltier element 21 and the bolster 1. Therefore, it is possible to effectively transfer heat from the guide post 3 to the heat absorbing portion 22 of the Peltier element 21 through the second heat transfer member 24 and effectively transfer heat from the heat dissipating portion 23 of the Peltier element 21 to the bolster 1 through the third heat transfer member 25. In addition, since the second and third heat transfer members 24 and 25 are made of a material having a thermal conductivity higher than that of the lower die holder 2, it is possible to further improve the heat transfer effect.

The press apparatus 200 includes the power generating unit that generates power using the relative movement between the guidepost 3 and the guide bush 4, and the Peltier element 21 is driven by power generated by the power generating unit. Therefore, an external power source for driving the Peltier element 21 is not required.

The power generating unit includes the guide post 3, the guide bush 4, and the coil 41 that is wound around one of the guide post 3 and the guide bush 4, and the other one of the guide post 3 and the guide bush 4 is made of a magnetized magnetic material. Therefore, when the guide post 3 and the guide bush 4 are moved relative to each other, a current is generated in the coil 41 by electromagnetic induction. Therefore, it is possible to effectively generate power using the relative movement between the guide post 3 and the guide bush 4.

In the second embodiment, the guide post 3 is made of a magnetized magnetic material and the coil 41 is wound around the guide bush 4. However, the invention is not limited thereto. For example, the guide bush 4 (or at least one of the upper die holder 5, the punch plate 9, and the punch 10) may be made of a magnetized magnetic material, and the coil 41 may be wound around the guide post 3 (or at least one of the lower die holder 2, the die plate 7, and the die 8). For example, when the coil 41 is wound around the guide post 3, it is necessary to arrange the coil 41 so as to avoid the sliding range of the guide bush 4. Therefore, for example, the guide post 3 maybe formed so as to extend higher than the top dead point position of the upper die holder 5 and the coil 41 may be wound around a portion of the guide post 3 higher than the top dead point position. Alternatively, the coil 41 maybe formed such that the inside diameter thereof is greater than the outer diameter of the guide bush 4, and the guide bush 4 made of a magnetized magnetic material may pass through the coil 41.

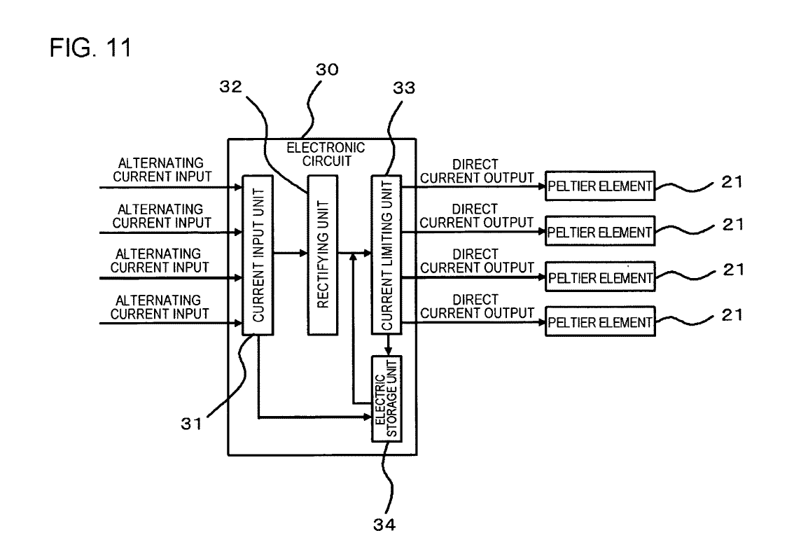

FIG. 11 is a block diagram illustrating a modification of the electronic circuit 30. In the second embodiment, for example, as in the modification shown in FIG. 11, the electronic circuit 30 may include an electric storage unit 34 that stores a direct current. In the modification, for example, the current limiting unit 33 inputs a current that is more than a predetermined upper limit to the electric storage unit 34. The electric storage unit 34 stores the current input from the current limiting unit 33. For example, when an alternating current is not input to the current input unit 31, a control signal indicating that an alternating current has not been input is output from the current input unit 31 to the electric storage unit 34. When receiving the control signal, the electric storage unit 34 outputs a direct current to each Peltier element 21 through the current limiting unit 33 to drive the Peltier elements 21. According to this modification, even when the guide post 3 and the guide bush 4 are not moved relative to each other, the Peltier element 21 can be driven to cool the guide post 3.

### Third Embodiment

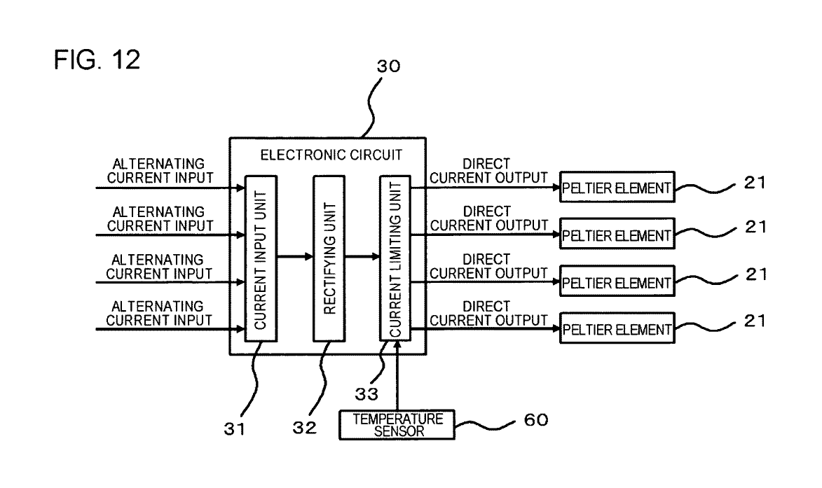

FIG. 12 is a block diagram illustrating the periphery of an electronic circuit 30 included in a press apparatus according to a third embodiment. As shown in FIG. 12, the press apparatus according to this embodiment has the same structure as the press apparatus 200 according to the second embodiment except that it includes a temperature sensor (temperature detecting unit) 60 which detects the temperature of the guide post 3.

From the relationship between the clearance C and the sliding load shown in FIG. 7, it is possible to finely and easily set the clearance C between the guide post 3 and the guide bush 4 at an interval of, for example, 1/10 μm to 1/100 μm by arbitrarily setting the temperature of the guide post 3.

In the third embodiment, the detection result of the temperature sensor 60 is input to the current limiting unit 33. As the temperature detected by the temperature sensor 60 increases, the upper limit of the current limited by the current limiting unit (current control unit) 33 increases.

In this way, as the temperature of the guide post 3 increases, the amount of current supplied to the Peltier element 21 increases. Therefore, it is possible to improve the cooling effect of the guide post 3 by the Peltier element 21. As a result, it is possible to control the temperature of the guide post 3 with high accuracy so as to be kept as constant as possible. When an excessively large amount of current is supplied to the Peltier element 21, the amount of heat generated from the Peltier element 21 increases, which may cause a reduction in the cooling effect of the guide post 3. Therefore, the current value supplied to the Peltier element 21 is controlled in a predetermined range such that the amount of heat generated from the Peltier element 21 is not too large.

As can be seen from the relationship shown in FIG. 7, it is possible to control two factors having a trade-off relation therebetween, such as the clearance C and the sliding load, in a desired state by setting the temperature of the guide post 3 in a predetermined range.

### Fourth Embodiment

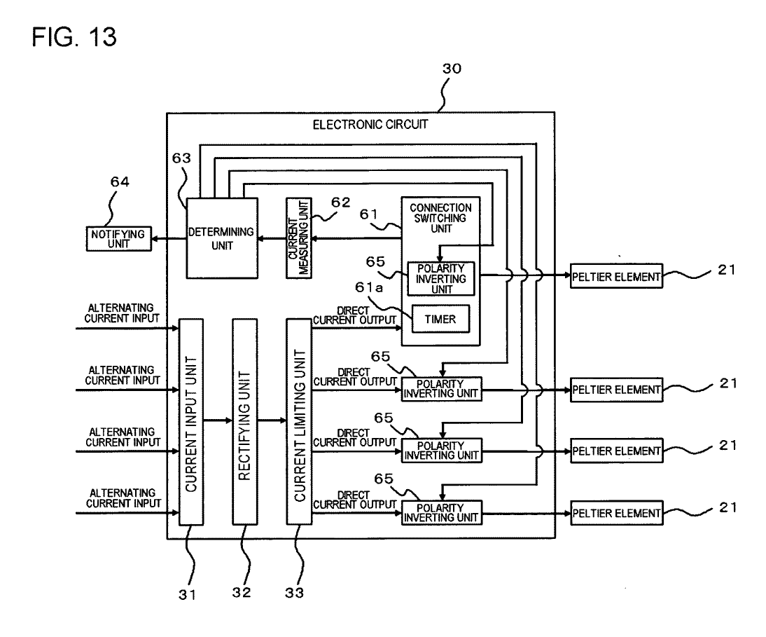

FIG. 13 is a block diagram illustrating the periphery of an electronic circuit 30 included in a press apparatus according to a fourth embodiment. As shown in FIG. 13, in the fourth embodiment, the electronic circuit 30 differs from that according to the second embodiment (FIG. 10) in that it includes a connection switching unit 61, a current measuring unit 62, a determining unit 63, and a polarity inverting unit 65. The press apparatus according to the fourth embodiment includes, for example, a notifying unit 64 that notifies the measurement result of a temperature difference between the guide post 3 and the bolster 1. In the fourth embodiment, the connection switching unit 61, the Peltier element 21, the current measuring unit 62, and the determining unit 63 form a temperature detecting unit. The press apparatus according to the fourth embodiment has the same structure as the press apparatus 200 according to the second embodiment except for the above-mentioned points.

The Peltier element 21 has a Seebeck effect in which electromotive force corresponding to a temperature difference between the heat absorbing portion 22 and the heat dissipating portion 23 is obtained. Therefore, it is possible to measure the temperature difference between the guide post 3 and the bolster 1 using the Peltier element 21.

The connection switching unit 61 switches the connect state between any one of a plurality of (for example, four) Peltier elements 21 and the current limiting unit 33 or the current measuring unit 62 between a first state and a second state. In the first state, the input/output terminals of the Peltier element 21 are disconnected from the current measuring unit 62 and are connected to the current limiting unit 33 such that a current is supplied from the current limiting unit 33 to the Peltier element 21. In the second state, the input/output terminals of the Peltier element 21 are disconnected from the current limiting unit 33 and are connected to the current measuring unit 62 such that the current measuring unit 62 measures the temperature difference between the heat absorbing portion 22 and the heat dissipating portion 23 of the Peltier element 21.

The measurement result (measured current value) of the current measuring unit 62 is input to the determining unit 63. The determining unit 63 stores the relationship between the measured current value and the temperature difference as a table in advance and determines a temperature difference corresponding to the measured current with reference to the table.

The determination result of the determining unit 63, that is, the measurement result of the temperature difference between the guide post 3 and the bolster 1 is input to the notifying unit 64. The notifying unit 64 includes, for example, a display device, such as a liquid crystal display device, or a speaker and notifies the measurement result input from the determining unit 63.

The connection switching unit 61 includes the polarity inverting unit 65, and the polarity inverting units 65 are also provided between other (for example, three) Peltier elements 21 that are not connected to the connection switching unit 61 and the current limiting unit 33.

When the guide post 3 is supercooled (for example, when the temperature of the guide post 3 is lower than that of the bolster 1), the determining unit 63 outputs a polarity inverting signal to each of the polarity inverting units 65 to invert the polarity of the direct current supplied from the current limiting unit 33 to the Peltier element 21. In this way, the heat absorbing portion 22 and the heat dissipating portion 23 of the Peltier element 21 are inverted (the heat absorbing portion 22 dissipates heat and the heat dissipating portion 23 absorbs heat). Therefore, the supercooling of the guide post 3 is reduced.

In addition, the connection switching unit 61 includes, for example, a timer 61a. Whenever the timer 61a measures that a predetermined period of time has elapsed, the connection switching unit 61 changes the connection state from the first state to the second state such that the current measuring unit 62 measures the temperature difference, and then changes the connection state from the second state to the first state.

According to the fourth embodiment, when the connection switching unit 61 changes the connection state between the Peltier element 21 and the current limiting unit 33 or the current measuring unit 62 from the first state to the second state, the supply of a direct current from the current limiting unit 33 to the Peltier element 21 is stopped and the input/output terminals of the Peltier element 21 are connected to the current measuring unit 62. Therefore, the current measuring unit 62 can measure the temperature difference between the guide post 3 and the bolster 1.

The polarity inverting unit 65 is controlled to invert the polarity of the direct current supplied from the current limiting unit 33 to the Peltier element 21 on the basis of the measured temperature difference, thereby inverting the heat absorbing portion 22 and the heat dissipating portion 23 of the Peltier element 21. In this way, it is possible to reduce the supercooling of the guide post 3.

In the fourth embodiment (FIG. 13), the connection switching unit 61 changes the connect state of only one of a plurality of (for example, four) Peltier elements 21. However, the connection switching unit 61 may change the connect state of each Peltier element 21.

In each of the above-described embodiments, the press apparatus is a semiconductor manufacturing apparatus. However, the invention can also be applied to press apparatuses other than the semiconductor manufacturing apparatus.

It is apparent that the present invention is not limited tot the above embodiments, and may be modified and changed without departing from the scope and spirit of the invention.

What is claimed is:

1. A press apparatus comprising:
a bolster;
a lower die holder that is mounted on said bolster to which a lower die is to be provided;
a guide post that is vertically provided in said lower die holder;
a guide bush that slides along said guide post;
an upper die holder that is fixed to said guide bush to which an upper die is to be provided; and
a heat transfer accelerating portion that contacts said guide post and said bolster and accelerates the transfer of heat from said guide post to said bolster.

2. The press apparatus according to claim 1,
wherein said heat transfer accelerating portion includes a first heat transfer member that is made of a material having a thermal conductivity higher than that of said guide post, and
said first heat transfer member contacts said guide post and said bolster.

3. The press apparatus according to claim 2,
wherein said first heat transfer member is made of a material having a thermal conductivity higher than said lower die holder.

4. The press apparatus according to claim 1,
wherein said heat transfer accelerating portion includes a Peltier element having a heat absorbing portion and a heat dissipating portion, and
said heat absorbing portion of said Peltier element is arranged so as to face said guide post and said heat dissipating portion is arranged so as to face said bolster.

5. The press apparatus according to claim 4,
wherein said heat transfer accelerating portion includes second and third heat transfer members that are made of a material having a thermal conductivity higher than that of said guide post,
said second heat transfer member contacts said guide post and said heat absorbing portion of said Peltier element, and
said third heat transfer member contacts said heat dissipating portion of said Peltier element and said bolster.

6. The press apparatus according to claim 5,
wherein said second and third heat transfer members are made of a material having a thermal conductivity higher than that of said lower die holder.

7. The press apparatus according to claim 4, further comprising:
a power generating unit that generates power using a relative movement between said guide post and said guide bush,
wherein said Peltier element is driven by power generated by said power generating unit.

8. The press apparatus according to claim 7,
wherein said power generating unit includes said guide post, said guide bush, and a coil that is wound around one of said guide post and said guide bush,
the other one of said guide post and said guide bush is made of a magnetized magnetic material, and
a current is generated in said coil by electromagnetic induction caused by said relative movement between said guide post and said guide bush.

9. The press apparatus according to claim 4, further comprising:
a temperature detecting unit that detects a temperature of said guide post; and
a current control unit that controls a current value supplied to said Peltier element on the basis of a detection result of said temperature detecting unit.

10. The press apparatus according to claim 4, further comprising:
a temperature detecting unit that detects a temperature of said guide post; and
a polarity inverting unit that inverts the polarity of a direct current supplied to said Peltier element on the basis of a detection result of said temperature detecting unit.

11. The press apparatus according to claim 1,
wherein said heat transfer accelerating portion is covered with a portion of said press apparatus other than said heat transfer accelerating portion and is not exposed from an outer surface of said press apparatus.

12. The press apparatus according to claim 11,
wherein a fitting hole to which a lower end of said guide post and said heat transfer accelerating portion are fitted is formed in said lower die holder,
said lower end of said guide post is fitted to said fitting hole and said guide post is vertically provided in said lower die holder, and
said heat transfer accelerating portion is interposed between said lower end of said guide post and an upper surface of said bolster in said fitting hole.

13. The press apparatus according to claim 12,
wherein a peripheral portion of said fitting hole of said lower die holder is made of a material having a thermal conductivity less than that of a portion of said lower die holder which is provided in the periphery of said peripheral portion.

14. The press apparatus according to claim 1,
wherein said upper die and said lower die press a semiconductor device, and
said press apparatus is a semiconductor manufacturing apparatus.

15. A method for manufacturing a semiconductor device, comprising:
pressing said semiconductor device using a semiconductor manufacturing apparatus that includes a bolster, a lower die holder that is mounted on said bolster to which a lower die is to be provided, a guide post that is vertically provided in said lower die holder, a guide bush that slides along said guide post, an upper die holder that is fixed to said guide bush to which an upper die is to be provided, and a heat transfer accelerating portion that contacts said guide post and said bolster and accelerates the transfer of heat from said guide post to said bolster, said upper and lower dies pressing said semiconductor device.
